(19) United States
(12) Patent Application Publication
(10) Pub. No.: US 2026/0068225 A1
(43) Pub. Date: Mar. 5, 2026

(54) GATE-ALL-AROUND DEVICE WITH COMMON MATERIAL FOR CHANNEL AND SOURCE/DRAIN EXTENSION (SDE)

(71) Applicant: INTERNATIONAL BUSINESS MACHINES CORPORATION, ARMONK, NY (US)

(72) Inventors: Shogo Mochizuki, Mechanicville, NY (US); Effendi Leobandung, Stormville, NY (US); Andrew Mark Greene, Slingerlands, NY (US)

(21) Appl. No.: 18/819,216

(22) Filed: Aug. 29, 2024

(51) Int. Cl. H01L 29/423; H01L 21/822; H01L 21/8238; H01L 27/06; H01L 27/092; H01L 29/06; H01L 29/66; H01L 29/775; H01L 29/786

(52) U.S. Cl. CPC H10D 30/6735; H10D 30/014; H10D 30/43; H10D 30/6757; H10D 62/121; H10D 64/017; H10D 84/0167; H10D 84/017; H10D 84/038; H10D 84/856; H10D 88/00; H10D 88/01

(57) ABSTRACT

Embodiments of the invention include a method for fabricating a semiconductor device and the resulting structure. A nanosheet stack of alternating nanosheets of sacrificial and semiconductor channel material nanosheets on a substrate is provided, where: a sacrificial gate structure and dielectric spacer material layer straddle over the stack. End portions of each of the sacrificial nanosheets are recessed. A thin-doped SiGe layer is formed on exposed surfaces of the semiconductor channel material nanosheet. A dielectric spacer material layer is formed within each gap. A source/drain region is formed. The sacrificial gate structure is removed. Each sacrificial semiconductor material nanosheet is removed. Exposed portions of each semiconductor channel material nanosheet are trimmed. Undoped SiGe is formed on exposed portions of each semiconductor channel. A thermal mix is performed, forming one or more SiGe nanosheets. A functional gate structure is formed, where the functional gate structure wraps around each suspended SiGe nanosheet.

### BACKGROUND

The present invention relates generally to the field of semiconductor devices and fabrication, and more particularly to the fabrication of a gate-all-around device.

The use of non-planar semiconductor devices such as, for example, semiconductor fin field effect transistors (FinFETs) is the next step in the evolution of complementary metal oxide semiconductor (CMOS) devices. One type of non-planar semiconductor device that has been touted as a viable option beyond the 7 nm technology node is a nanosheet containing device. By “nanosheet containing device” it is meant that the device contains one or more layers of semiconductor channel material portions having a vertical thickness that is substantially less than its width.

Nanosheet formation relies on the selective removal of one semiconductor material (e.g., silicon) to another semiconductor material (e.g., a silicon germanium alloy) to form suspended nanosheets for gate-all-around devices. Source/drain (S/D) regions for nanosheet containing devices are currently formed by epitaxial growth of a semiconductor material upwards from an exposed surface of the semiconductor substrate and from sidewalls of each nanosheet.

### SUMMARY

Embodiments of the invention include a semiconductor structure that includes one or more stacked and suspended silicon germanium (SiGe) semiconductor channel material nanosheets located above a semiconductor substrate. The structure further includes a functional gate structure surrounding a portion of each SiGe semiconductor channel material nanosheet of the one or more stacked and suspended SiGe semiconductor channel material nanosheets. The structure further includes a source/drain region on each side of the functional gate structure and physically contacting sidewalls of each SiGe semiconductor channel material nanosheet of the one or more stacked and suspended SiGe semiconductor channel material nanosheets.

Embodiments of the invention include a semiconductor structure that includes one or more stacked and suspended silicon germanium (SiGe) nanosheets located above a semiconductor substrate, where each SiGe nanosheet comprises a plurality of portions comprising: a first portion between two inner gate spacers, the first portion formed with doped SiGe; and a second portion formed with undoped SiGe. The structure further includes a functional gate structure surrounding the second portion of each SiGe semiconductor channel material nanosheet of the one or more stacked and suspended SiGe semiconductor channel material nanosheets. The structure further includes a source/drain region on each side of the functional gate structure and physically contacting sidewalls of each SiGe semiconductor channel material nanosheet of the one or more stacked and suspended SiGe semiconductor channel material nanosheets.

Embodiments of the invention include a method for fabricating a semiconductor device. The method includes providing a nanosheet stack of alternating nanosheets of a sacrificial semiconductor material nanosheet and a semiconductor channel material nanosheet located on a surface of a semiconductor substrate, where a sacrificial gate structure and a dielectric spacer material layer straddle over the nanosheet stack. The method can also include recessing end portions of each of the sacrificial semiconductor material nanosheets to provide a gap between each of the semiconductor channel material nanosheets. The method can also include forming a thin-doped silicon germanium (SiGe) layer on exposed surfaces of the semiconductor channel material nanosheet and the semiconductor substrate. The method can also include forming an additional dielectric spacer material layer on the thin-doped SiGe layer and within each gap. The method can also include forming a source/drain region by epitaxial growth of a semiconductor material on the physically exposed sidewalls of the thin-doped SiGe layer. The method can also include removing the sacrificial gate structure. The method can also include removing each sacrificial semiconductor material nanosheet to suspend each semiconductor channel material nanosheet. The method can also include trimming exposed portions of each semiconductor channel material nanosheet. The method can also include forming undoped SiGe on exposed portions of each semiconductor channel. The method can also include performing a thermal mix, resulting in the undoped SiGe, the thin-doped SiGe, and each semiconductor channel becoming one or more silicon germanium (SiGe) semiconductor channel material nanosheets. The method can also include forming a functional gate structure in regions occupied by the sacrificial gate structure and each sacrificial semiconductor material nanosheet, where the functional gate structure wraps around each suspended SiGe semiconductor channel material nanosheet.

### BRIEF DESCRIPTION OF THE DRAWINGS

FIG. 1A depicts a cross-sectional view, along a first direction, and FIG. 1B depicts a cross-sectional view, along a second direction, of a device during the method of forming the device, the device including a semiconductor substrate, a semiconductor material stack upon, and a dummy gate upon which embodiments of the invention can be fabricated, in accordance with an embodiment of the invention.

FIG. 2A depicts a cross-sectional view, along a first direction, and FIG. 2B depicts a cross-sectional view, along a second direction, of a process of recessing the sacrificial semiconductor material layer, in accordance with an embodiment of the invention.

FIG. 3A depicts a cross-sectional view, along a first direction, and FIG. 3B depicts a cross-sectional view, along a second direction, of a process of forming a thin-doped layer, in accordance with an embodiment of the invention.

FIG. 4A depicts a cross-sectional view, along a first direction, and FIG. 4B depicts a cross-sectional view, along a second direction, of a process forming inner spacers, in accordance with an embodiment of the invention.

FIG. 5A depicts a cross-sectional view, along a first direction, and FIG. 5B depicts a cross-sectional view, along a second direction, of a process of forming source/drain regions, in accordance with an embodiment of the invention.

FIG. 6A depicts a cross-sectional view, along a first direction, and FIG. 6B depicts a cross-sectional view, along a second direction, of a process of forming an interlayer dielectric (ILD) and removing each sacrificial gate structure, in accordance with an embodiment of the invention.

FIG. 7A depicts a cross-sectional view, along a first direction, and FIG. 7B depicts a cross-sectional view, along a second direction, of a process of removing each recessed sacrificial semiconductor material nanosheet, in accordance with an embodiment of the invention.

FIG. 8A depicts a cross-sectional view, along a first direction, and FIG. 8B depicts a cross-sectional view, along a second direction, of a process of trimming exposed portions of the semiconductor material layer, in accordance with an embodiment of the invention.

FIG. 9A depicts a cross-sectional view, along a first direction, and FIG. 9B depicts a cross-sectional view, along a second direction, of a process of growing undoped channel material on exposed surfaces of the semiconductor channel material layer and the semiconductor substrate, in accordance with an embodiment of the invention.

FIG. 10A depicts a cross-sectional view, along a first direction, and FIG. 10B depicts a cross-sectional view, along a second direction, of the structure subsequent to a thermal mix process resulting in the formation of continuous common material channel nanosheets, in accordance with an embodiment of the invention.

FIG. 11A depicts a cross-sectional view, along a first direction, and FIG. 11B depicts a cross-sectional view, along a second direction, of a process of forming a functional gate structure, in accordance with an embodiment of the invention.

### DETAILED DESCRIPTION

Embodiments of the present invention recognize that having a barrier (e.g., silicon (Si)) between a channel (e.g., silicon germanium (SiGe)) and a source/drain region can cause parasitic resistance. Embodiments of the present invention recognize that creating a channel with a continuous and common material channel, from the source to the drain, can eliminate a high potential barrier and eliminate high parasitic resistance. Embodiments of the present invention describe structures and methods for creating a gate-all-around nanosheet device structure with a common silicon germanium channel that spans from the source to the drain.

Embodiments of the present invention describe an approach for fabricating a semiconductor device, the approach including forming an alternating stack of Si and SiGe layers and a dummy gate. Embodiments of the present invention further describe forming a spacer reactive ion etch and a source/drain recess within the alternating stack of Si and SiGe layers. Embodiments of the present invention further describe selectively indenting exposed portions of the SiGe layers. Embodiments of the present invention further describe growing thin-doped SiGe layers on the Si nanosheets. Embodiments of the present invention further describe forming inner spacers via, for example, dielectric deposition and etch back processes. Embodiments of the present invention further describe removing the dummy gate and selectively removing the SiGe layers to form a plurality of suspended Si nanosheets. Embodiments of the present invention further describe trimming the Si nanosheets. Embodiments of the present invention further describe growing undoped channel material (e.g., SiGe) on the Si nanosheet channel and performing a thermal mix to result in both the Si nanosheet and a source/drain extension (SDE) structure present in between the inner spacers to become SiGe and form a continuous channel of SiGe between two source/drain regions. Embodiments of the present invention further describe the formation of high-κ dielectric and work function metal (e.g., gate conductor material) that surrounds each of the SiGe channels.

Embodiments of the present invention describe structures and methods for creating a gate-all-around nanosheet transistor with a controlled source/drain extension (SDE) structure. Embodiments of the present invention describe structures and methods for creating a continuous SiGe region channel connecting two source/drain regions. Embodiments of the present invention further describe that the SDE region is a region under a spacer that is formed with doped SiGe and that the SDE dopants may be different dopants when compared to the source/drain region dopants. Embodiments of the present invention further describe that the channel region is formed with undoped SiGe. Embodiments of the present invention further describe that the germanium (Ge) profile in the channel nanosheet has a uniform or graded profile. Embodiments of the present invention further recognize that the SiGe region in the SDE and the channel region are each formed with Ge diffusion from different cladding SiGe regions deposited on SDE (e.g., post SiGe indent) and channel (e.g., post silicon (Si) nanosheet trim).

The following description with reference to the accompanying drawings is provided to assist in a comprehensive understanding of embodiments of the invention as defined by the claims and their equivalents. It includes various specific details to assist in that understanding but these are to be regarded as merely examples. Accordingly, those of ordinary skill in the art will recognize that various changes and modifications of the embodiments described herein can be made without departing from the scope and spirit of embodiments of the invention. Some of the process steps, depicted, can be combined as an integrated process step. In addition, descriptions of well-known functions and constructions may be omitted for clarity and conciseness.

Detailed embodiments of the claimed structures and methods are disclosed herein; however, it is to be understood that the disclosed embodiments are merely illustrative of the claimed structures and methods that may be embodied in various forms. In addition, each of the examples given in connection with the various embodiments are intended to be illustrative, and not restrictive. Further, the figures are not necessarily to scale, some features may be exaggerated to show details of particular components. Therefore, specific structural and functional details disclosed herein are not to be interpreted as limiting, but merely as a representative basis for teaching one skilled in the art to variously employ the methods and structures of the present disclosure. It is also noted that like and corresponding elements are referred to by like reference numerals.

The terms and words used in the following description and claims are not limited to the bibliographical meanings but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It is to be understood that the singular forms “a,” “an,” and “the” include plural referents unless the context clearly dictates otherwise. Thus, for example, reference to “a component surface” includes reference to one or more of such surfaces unless the context clearly dictates otherwise.

References in the specification to “one embodiment”, “other embodiment”, “another embodiment”, “an embodiment,” etc., indicate that the embodiment described may include a particular feature, structure or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to affect such feature, structure, or characteristic in connection with other embodiments whether or not explicitly described. It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

For purposes of the description hereinafter, the terms “upper,” “right,” “left,” “vertical,” “horizontal,” “top,” “bottom,” and derivatives thereof shall relate to the disclosed structures and methods, as oriented in the drawing Figures. The terms “overlaying,” “atop,” “positioned on,” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

It will be understood that when an element as a layer, region or substrate is referred to as being “on” or “over” another element, it can be directly on the other element, or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

In the interest of not obscuring the presentation of embodiments of the present invention, in the following detailed description, some processing steps or operations that are known in the art may have been combined for presentation and illustration purposes and in some instances may have not been described in detail. In other instances, some processing steps or operations that are known in the art may not be described at all. It should be understood that the following description is rather focused on the distinctive features or elements of various embodiments of the present invention.

Detailed embodiments of the claimed structures and methods are disclosed herein. The method steps described below do not form a complete process flow for manufacturing integrated circuits on semiconductor chips. The present embodiments can be practiced in conjunction with the integrated circuit fabrication techniques for semiconductor chips and devices currently used in the art, and only so much of the commonly practiced process steps are included as are necessary for an understanding of the described embodiments. The figures represent cross-section portions of a semiconductor chip or a substrate, such as a semiconductor wafer during fabrication, and are not drawn to scale, but instead are drawn to illustrate the features of the described embodiments. Specific structural and functional details disclosed herein are not to be interpreted as limiting, but merely as a representative basis for teaching one skilled in the art to variously employ the methods and structures of the present disclosure. In the description, details of well-known features and techniques may be omitted to avoid unnecessarily obscuring the presented embodiments.

Deposition processes as used herein include but are not limited to ionized plasma vapor deposition (iPVD), plasma vapor deposition (PVD), electroplating atomic layer deposition (ALD), plasma-enhanced chemical vapor deposition (PECVD), CVD, gas cluster ion beam (GCIB) deposition, ionized plasma vapor deposition (iPVD), PVD, or electroplating.

Selectively etching as used herein includes but is not limited to patterning using one of lithography, photolithography, an extreme ultraviolet (EUV) lithography process, or any other known semiconductor patterning process followed by one or more the etching processes. Various materials are referred to herein as being removed or “etched” where etching generally refers to one or more processes implementing the removal of one or more materials while leaving other protected areas of the materials that are masked during the lithography processes unaffected. Some examples of etching processes include but are not limited to the following processes, such as a dry etching process using a reactive ion etch (RIE) or ion beam etch (IBE), a wet chemical etch process, or a combination of these etching processes. A dry etch may be performed using a plasma. Plasma systems can operate in several modes by adjusting the parameters of the plasma. Ordinary plasma etching produces energetic free radicals, neutrally charged, that react at the surface of the wafer and is an isotopic etch process (e.g., removes material in all directions. Ion milling, sputter etching, or reactive ion etching (RIE) bombards the wafer with energetic ions of noble gases that approach the wafer approximately from one direction, and therefore, these processes are anisotropic or a directional etching process.

The terms “epitaxially growing and/or depositing” and “epitaxially grown and/or deposited” mean the growth of a semiconductor material on a deposition surface of a semiconductor material, in which the semiconductor material being grown has the same crystalline characteristics as the semiconductor material of the deposition surface. In an epitaxial deposition process, the chemical reactants provided by the source gases are controlled and the system parameters are set so that the depositing atoms arrive at the deposition surface of the semiconductor substrate with sufficient energy to move around on the surface and orient themselves to the crystal arrangement of the atoms of the deposition surface. Therefore, an epitaxial semiconductor material has the same crystalline characteristics as the deposition surface on which it is formed.

Each reference number may refer to an item individually or collectively as a group. For example, sacrificial gate portion 150 may refer to a single sacrificial gate portion 150 or multiple sacrificial gate portions 150.

The present invention will now be described in detail with reference to the Figures. The figures provide a schematic cross-sectional illustration of semiconductor devices at intermediate stages of fabrication, according to one or more embodiments of the invention. The figures provide schematic representations of the devices of the invention and are not to be considered accurate or limiting with regards to device element scale.

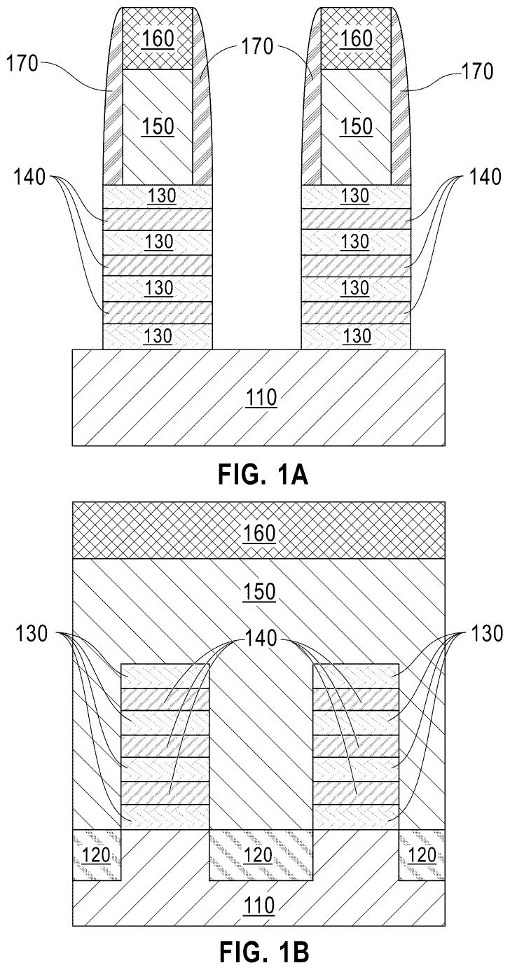

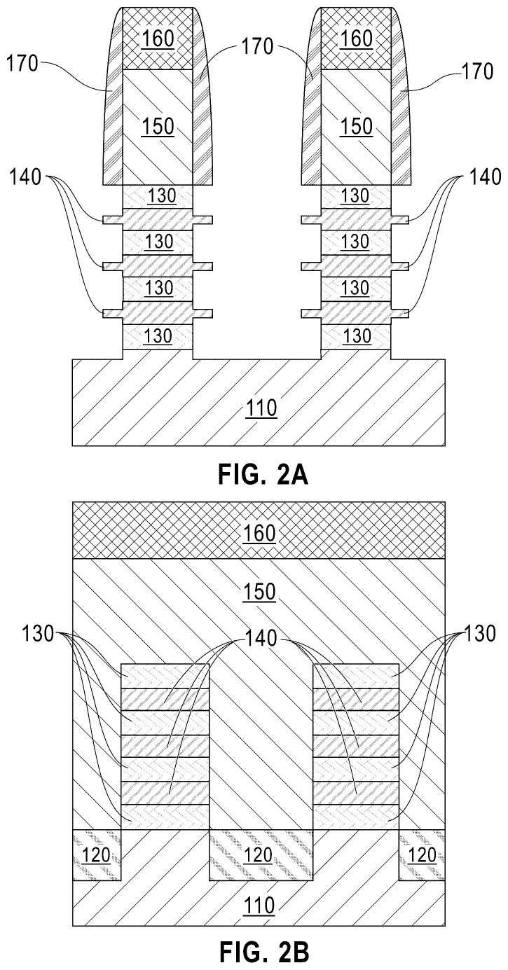

FIG. 1A depicts a first cross-sectional view, along a first direction, and FIG. 2B depicts a second cross-sectional view, along a second direction, in accordance with an embodiment of the present invention. More particularly, FIGS. 1A-1B depict the device during the method of forming the device subsequent to steps such as nanosheet stack patterning, shallow trench isolation (STI) formation dummy gate formation, and source/drain recess formation.

The semiconductor structure of FIGS. 1A-2B includes a semiconductor substrate 110 upon which embodiments of the invention can be fabricated.

Semiconductor substrate 110 may be composed of a silicon containing material. Silicon containing materials include, but are not limited to, silicon, single crystal silicon, polycrystalline silicon, SiGe, single crystal SiGe, polycrystalline SiGe, or silicon doped with carbon (C), amorphous silicon, and combinations and multi-layers thereof. Semiconductor substrate 210 can also be composed of other semiconductor materials, such as germanium (Ge), and compound semiconductor substrates, such as type III/V semiconductor substrates, e.g., gallium arsenide (GaAs). In general, semiconductor substrate 110 is a smooth surface substrate. In some embodiments (not shown), semiconductor substrate 110 can be a partially processed complementary metal-oxide semiconductor (CMOS) integrated wafer with transistors and wiring levels or gate electrodes embedded beneath the surface.

In some embodiments, a buried oxide layer (not depicted) is present above semiconductor substrate 110. The buried oxide layer acts as an electrical insulator.

Stacked FETs are depicted in FIGS. 1A-1B and may generally be formed as described herein.

In the depicted embodiment, a semiconductor material stack (sacrificial semiconductor material layer 130, semiconductor channel material layer 140) is formed upon semiconductor substrate 110. The semiconductor material stack includes vertically aligned alternating layers of sacrificial semiconductor material layer 130 and semiconductor channel material layer 140. The semiconductor material stack is sequentially formed upon semiconductor substrate 110. As mentioned above, the semiconductor material stack includes sacrificial semiconductor material layers 130 and semiconductor channel material layers 140, which alternate one atop the other. In FIGS. 1A-1B, and only by way of one example, the semiconductor material stack includes four layers of sacrificial semiconductor material layer 130 and three layers of semiconductor channel material layer 140. The semiconductor material stacks that can be employed in embodiments of the present invention are not limited to the specific embodiment illustrated in FIGS. 1A-1B. Instead, the semiconductor material stack can include any number of sacrificial semiconductor material layers 130 and semiconductor channel material layers 140. The semiconductor material stack is used to provide a gate-all-around device that includes vertically stacked semiconductor channel material nanosheets for a p-channel field-effect transistor (pFET) or n-channel field-effect transistor (nFET) device.

Each sacrificial semiconductor material layer 130 is composed of a first semiconductor material which differs in composition from at least an upper portion of semiconductor substrate 110. In one embodiment, each sacrificial semiconductor material layer 130 is composed of SiGe. In such an embodiment, the silicon germanium alloy content of the sacrificial semiconductor material layer 130 may have a germanium content that is less than fifty atomic percent germanium. In one example, the SiGe alloy that makes up the sacrificial semiconductor material layer 130 has a germanium content from ten atomic percent germanium to fifty atomic percent germanium. The first semiconductor material, for each sacrificial semiconductor material layer 130, can be formed utilizing an epitaxial growth or deposition process.

Each semiconductor channel material layer 140 is composed of a second semiconductor material that has a different etch rate than the first semiconductor material of the sacrificial semiconductor material layers 130. The second semiconductor material of each semiconductor channel material layer 140 may be the same as, or different than, the semiconductor material of, at least, the upper portion of semiconductor substrate 110. The second semiconductor material can be, for example, silicon. The second semiconductor material can be a SiGe alloy having a germanium content of ten to fifty atomic percent germanium and the first semiconductor material is different than the second semiconductor material.

In one example, at least the upper portion of semiconductor substrate 110 and each semiconductor channel material layer 140 is composed of Si or a III-V compound semiconductor, while each sacrificial semiconductor material layer is composed of a SiGe alloy. The second semiconductor material, for each semiconductor channel material layer 140, can be formed utilizing an epitaxial growth or deposition process.

Semiconductor material stack (sacrificial semiconductor material layer 130, semiconductor channel material layer 140) can be formed by sequential epitaxial growth of alternating layers of the first semiconductor material and the second semiconductor material. Following epitaxial growth of the topmost layer of the semiconductor material stack (sacrificial semiconductor material layer 130, semiconductor channel material layer 140) a patterning process may be used to provide the semiconductor material stack (sacrificial semiconductor material layer 130, semiconductor channel material layer 140). Patterning may be achieved by lithography and etching as is well known to those skilled in the art.

The terms “epitaxially growing and/or depositing” and “epitaxially grown and/or deposited” mean the growth of a semiconductor material on a deposition surface of a semiconductor material, in which the semiconductor material being grown has the same crystalline characteristics as the semiconductor material of the deposition surface. In an epitaxial deposition process, the chemical reactants provided by the source gases are controlled and the system parameters are set so that the depositing atoms arrive at the deposition surface of the semiconductor substrate with sufficient energy to move around on the surface and orient themselves to the crystal arrangement of the atoms of the deposition surface. Therefore, an epitaxial semiconductor material has the same crystalline characteristics as the deposition surface on which it is formed.

Examples of various epitaxial growth process apparatuses that can be employed in the present application include, e.g., rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE). The temperature for epitaxial deposition typically ranges from 550° C. to 900° C. Although higher temperature typically results in faster deposition, the faster deposition may result in crystal defects and film cracking. The epitaxial growth of the first and second semiconductor materials that provide the sacrificial semiconductor material layers 130 and the semiconductor channel material layers 140, respectively, can be performed utilizing any well-known precursor gas or gas mixture. Carrier gases like hydrogen, nitrogen, helium and argon can be used.

The sacrificial semiconductor material layers 130 that constitutes the semiconductor material stack may have a thickness from five nm to fifteen nm, while the semiconductor channel material layers 140 that constitute the semiconductor material stack may have a thickness from five nm to fifteen nm. Each sacrificial semiconductor material layer 130 may have a thickness that is the same as, or different from, a thickness of each semiconductor channel material layer 140. In an embodiment, each sacrificial semiconductor material layer 130 has an identical thickness. In an embodiment, each semiconductor channel material layer 140 has an identical thickness.

Following epitaxial growth of the topmost layer of the semiconductor material stack (sacrificial semiconductor material layer 130, semiconductor channel material layer 140), a patterning process may be used to provide the semiconductor material stack. Patterning may be achieved by lithography and etching as is well known to those skilled in the art.

Shallow trench isolation (STI) layer 120 may be formed by patterning a hardmask layer (not shown) using lithography and etching such that top surfaces of portions of semiconductor substrate 110 are exposed corresponding to locations where trenches for STI layer 120 are desired. Accordingly, the hardmask layer is patterned such that semiconductor substrate 110 is exposed at desired trench locations for STI layer 120.

Physically exposed portions of semiconductor substrate 110 are removed. The removing of portions of semiconductor substrate 110 can be performed utilizing an anisotropic etching process such as, for example, reactive ion etching (RIE). Portions of semiconductor substrate 110 remain beneath the hardmask.

A sacrificial gate structure and dielectric spacer material layer 170 (also referred to as a gate spacer) may be formed. Each sacrificial gate structure is located on a first side and a second side of the semiconductor material stack (sacrificial semiconductor material layer 130, semiconductor channel material layer 140) and spans across a topmost surface of a portion of the semiconductor material stack (sacrificial semiconductor material layer 130, semiconductor channel material layer 140). Each sacrificial gate structure thus straddles over a portion of the semiconductor material stack (sacrificial semiconductor material layer 130, semiconductor channel material layer 140). The dielectric spacer material layer 170 is present on sidewalls of each sacrificial gate structure.

Each sacrificial gate structure may include a single sacrificial material portion or a stack of two or more sacrificial material portions (i.e., at least one sacrificial material portion). In one embodiment, the at least one sacrificial material portion comprises, from bottom to top, a sacrificial gate portion 150 and a sacrificial dielectric cap portion 160. In some embodiments, the sacrificial dielectric cap portion 160 can be omitted and only a sacrificial gate portion 150 is formed. The at least one sacrificial material portion can be formed by forming a blanket layer (or layers) of a material (or various materials) and then patterning the material (or various materials) by lithography and an etch. In some embodiments, a multilayered dielectric structure comprising different dielectric materials, e.g., silicon dioxide, and a high-κ dielectric can be formed and used as the sacrificial gate portion 150.

A blanket layer of a sacrificial gate material can be formed on the semiconductor material stack (sacrificial semiconductor material layer 130, semiconductor channel material layer 140). The sacrificial gate material can include any material including, for example, polysilicon, amorphous silicon, an elemental metal (e.g., tungsten, titanium, tantalum, aluminum, nickel, ruthenium, palladium, and platinum), an alloy of at least two elemental metals, or multilayered combinations thereof. The sacrificial gate material can be formed utilizing a deposition process including, for example, chemical vapor deposition (CVD), plasma enhanced chemical vapor deposition (PECVD), physical vapor deposition (PVD), sputtering, atomic layer deposition (ALD) or other like deposition processes.

After forming the blanket layer of sacrificial gate material, a blanket layer of a sacrificial gate cap material can be formed. The sacrificial gate cap material may include a hardmask material such as, for example, silicon dioxide and/or silicon nitride. The sacrificial gate cap material can be formed by any suitable deposition process such as, for example, chemical vapor deposition (CVD) or plasma enhanced chemical vapor deposition (PECVD).

After providing the above mentioned sacrificial material stack (or any subset of the sacrificial materials), lithography and etching can be used to pattern the sacrificial material stack (or any subset of the sacrificial materials) and to provide the at least one sacrificial gate structure. The remaining portions of the sacrificial gate material constitute a sacrificial gate portion 150, and the remaining portions of the sacrificial dielectric cap material constitute a sacrificial dielectric cap portion 160.

After providing the sacrificial gate structure, the dielectric spacer material layer 170 can be formed on exposed surfaces of each sacrificial gate structure. The dielectric spacer material layer 170 can be formed by first providing a dielectric spacer material and then etching the dielectric spacer material. One example of a dielectric spacer material (i.e., dielectric spacer material layer 170) that may be employed in the present application is silicon nitride. In general, the dielectric spacer material layer 170 comprises any dielectric spacer material, including, for example, a dielectric nitride, dielectric oxide, and/or dielectric oxynitride. More specifically, the dielectric spacer material layer 170 may be, for example, SiBCN, SiBN, SiOCN, SiON, SiCO, or SiC. In one example, the dielectric spacer material layer 170 is composed of a dielectric material such as SiO₂.

The dielectric spacer material that provides the dielectric spacer material layer 170 may be provided by a deposition process including, for example, ALD, chemical vapor deposition (CVD), plasma enhanced chemical vapor deposition (PECVD), or physical vapor deposition (PVD). The etch used to provide the dielectric spacer material layer may comprise a dry etching process such as, for example, reactive ion etching.

Recesses may be formed within the semiconductor material stack, creating the formation of nanosheet stacks of alternating nanosheets of sacrificial semiconductor material layers 130 and semiconductor channel material layers 140 that are under at least one sacrificial gate structure (sacrificial gate portion 150 and sacrificial dielectric cap portion 160) and dielectric spacer material layer 170.

The nanosheet stack is formed by removing physically exposed portions of the semiconductor material stack (sacrificial semiconductor material layer 130, semiconductor channel material layer 140) that are not protected by the least one sacrificial gate structure (sacrificial gate portion 150 and sacrificial dielectric cap portion 160) and the dielectric spacer material layer 170. In general, each recess may include the eventual location of source/drain region 510 for the semiconductor device.

The removing of the portions of the semiconductor material stack (sacrificial semiconductor material layer 130, semiconductor channel material layer 140) not covered by the least one sacrificial gate structure (sacrificial gate portion 150 and sacrificial dielectric cap portion 160) and the dielectric spacer material layer 170 can be performed utilizing an anisotropic etching process such as, for example, reactive ion etching (RIE). Portions of the semiconductor material stack (sacrificial semiconductor material layer 130, semiconductor channel material layer 140) remain beneath at least one sacrificial gate structure (sacrificial gate portion 150 and sacrificial dielectric cap portion 160) and the dielectric spacer material layer 170. The remaining portion of the semiconductor material stack (sacrificial semiconductor material layer 130, semiconductor channel material layer 140) that is present beneath the at least one sacrificial gate structure (sacrificial gate portion 150 and sacrificial dielectric cap portion 160) and the dielectric spacer material layer 170 is referred to as a nanosheet stack.

Each nanosheet stack includes alternating nanosheets of remaining portions of each sacrificial semiconductor material layer 130 and remaining portions of each semiconductor channel material layer 140. Each nanosheet (i.e., sacrificial semiconductor material layer 130 or semiconductor channel material layer 140) that constitutes the nanosheet stack has a thickness as mentioned above for the individual sacrificial semiconductor material layers 130 and semiconductor channel material layers 140, and a width from 10 nm to 200 nm. In some embodiments, the sidewalls of each sacrificial semiconductor material layer 130 are vertically aligned to sidewalls of each semiconductor channel material layer 140, and the vertically aligned sidewalls of the nanosheet stack are vertically aligned to an outmost sidewall of dielectric spacer material layer.

FIG. 2A depicts a first cross-sectional view, along a first direction, and FIG. 2B depicts a second cross-sectional view, along a second direction, of fabrication steps, in accordance with an embodiment of the present invention. FIGS. 2A-2B depict the recessing of sacrificial semiconductor material layer 130, which also may result in the indentation or thinning of each semiconductor channel material layer 140.

Each recessed sacrificial semiconductor material layer 130 has a width that is less than the original width of each sacrificial semiconductor material layer 130 (see FIG. 2A). The recessing of each sacrificial semiconductor material layer 130 provides a gap between each neighboring pair of semiconductor channel material layer 140 within a given nanosheet stack. The recessing of each sacrificial semiconductor material layer 130 may be performed utilizing a lateral etching process that is selective in removing physically exposed end portions of each sacrificial semiconductor material layer 130 relative to each semiconductor channel material layer 140. In some embodiments, the etching process utilized results in a thinning of exposed portions of each semiconductor channel material layer 140 (see FIG. 2A).

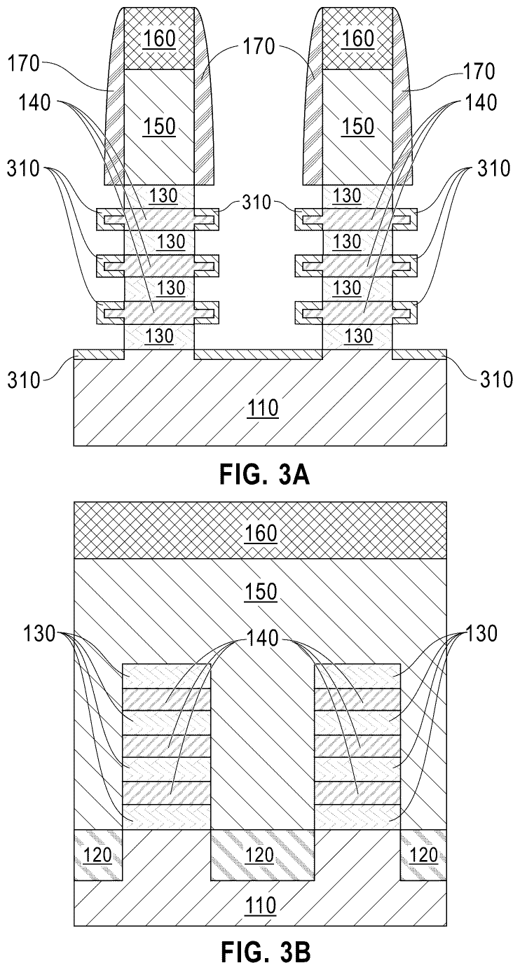

FIG. 3A depicts a first cross-sectional view, along a first direction, and FIG. 3B depicts a second cross-sectional view, along a second direction, of fabrication steps, in accordance with an embodiment of the present invention. FIGS. 3A-3B depict the formation thin-doped layer 310.

Thin-doped layer 310 is formed by epitaxial growth of a semiconductor material on physically exposed surfaces of semiconductor substrate 110 and physically exposed surfaces and sidewalls of each semiconductor channel material layer 140. The thin-doped layer forms a film or liner covering the surfaces of semiconductor substrate 110 and physically exposed surfaces and sidewalls of each semiconductor channel material layer 140.

Each thin-doped layer 310 includes a semiconductor material and a dopant. The semiconductor material that provides each thin-doped layer 310 can be selected from one of the semiconductor materials mentioned above for the semiconductor substrate 110 or semiconductor channel material layer 140. In some embodiments, the semiconductor material that provides each source/drain region 510 may comprise a same semiconductor material as that which provides semiconductor channel material layer 140. In other embodiments, the semiconductor material that provides each thin-doped layer 310 may comprise a different semiconductor material than that which provides semiconductor channel material layer 140. For example, the semiconductor material that provides each thin-doped layer 310 may comprise SiGe or a SiGe alloy, while semiconductor channel material layer 140 may comprise silicon.

The dopant that is present in each thin-doped layer 310 can be either a p-type dopant or an n-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium, and indium. “N-type” refers to the addition of impurities that contributes free electrons to an intrinsic semiconductor. In a silicon containing semiconductor material, examples of n-type dopants, i.e., impurities, include, but are not limited to, antimony, arsenic, and phosphorous. In one embodiment, the dopant that can be present in each thin-doped layer 310 can be introduced into the precursor gas that provides each thin-doped layer 310. In another embodiment, the dopant can be introduced into an intrinsic semiconductor layer by utilizing one of ion implantation or gas phase doping. In one example, each thin-doped layer 310 comprises a silicon germanium alloy that is doped with a p-type dopant such as, for example, boron. In some embodiments, the dopant species utilized is a different dopant species as compared to dopants subsequently utilized in the formation of source/drain region 510. As mentioned above, each thin-doped layer 310 is formed by an epitaxial growth (or deposition) process, as is defined above, such as, but not limited to CVD.

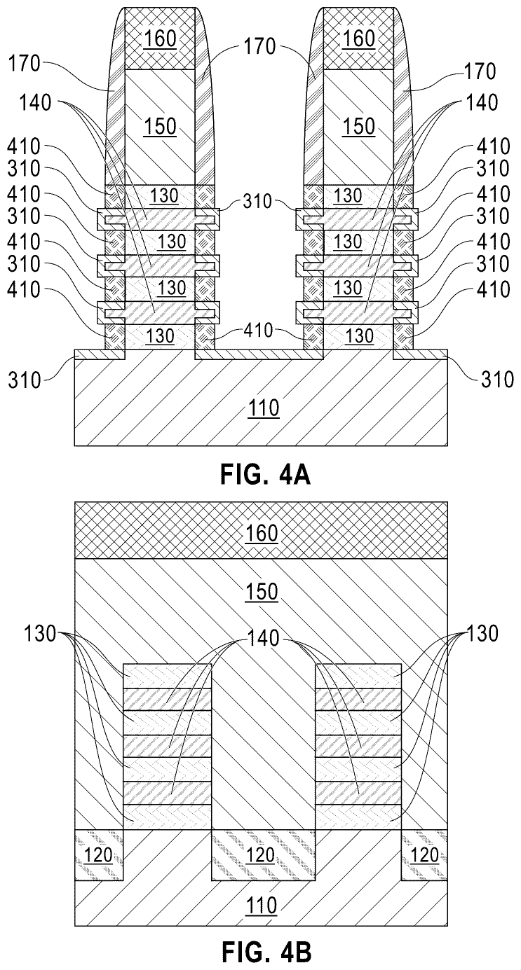

FIG. 4A depicts a first cross-sectional view, along a first direction, and FIG. 4B depicts a second cross-sectional view, along a second direction, of fabrication steps, in accordance with an embodiment of the present invention. FIGS. 4A-4B depict the formation of inner spacers 410.

As previously described, subsequent to the recession of each sacrificial semiconductor material layer 130, each recessed sacrificial semiconductor material layer 130 has a width that is less than the original width of each sacrificial semiconductor material layer 130. The recessing of each sacrificial semiconductor material layer 130 and the formation of thin-doped layer 310 creates a gap between each neighboring pair of semiconductor channel material layer 250 and each surrounding thin-doped layer 310 within a given nanosheet stack.

The additional dielectric spacer material that is added can be compositionally the same as the dielectric spacer material layer 170 mentioned above. In one example, the additional dielectric spacer material and the dielectric spacer material layer 170 are both composed of silicon nitride. The inner spacer 410 is formed by a conformal dielectric liner deposition followed by isotropic etching back the deposited liner.

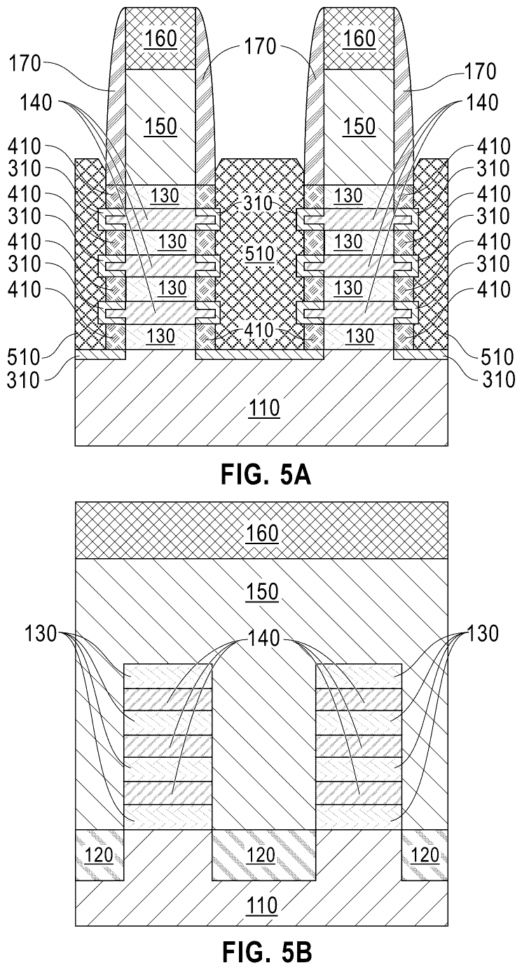

FIG. 5A depicts a first cross-sectional view, along a first direction, and FIG. 5B depicts a second cross-sectional view, along a second direction, of fabrication steps, in accordance with an embodiment of the present invention. FIGS. 5A-5B depict the formation of source/drain region 510 on thin-doped layer 310 and along the sidewalls of each nanosheet stack.

Source/drain region 510 is formed by epitaxial growth of a semiconductor material on physically exposed top surfaces thin-doped layer 310 and physically exposed sidewalls of each thin-doped layer 310. The source/drain region 510 has a bottommost surface that directly contacts a topmost surface of portions of thin-doped layer that are on top of semiconductor substrate 110.

Each source/drain region 510 includes a semiconductor material and a dopant. The semiconductor material that provides each source/drain region 510 can be selected from one of the semiconductor materials mentioned above for the semiconductor substrate 110. In some embodiments, the semiconductor material that provides each source/drain region 510 may comprise a same semiconductor material as that which provides semiconductor channel material layer 140. In some embodiments, the semiconductor material that provides each source/drain region 510 may comprise a same semiconductor material as that which provides thin-doped layer 310. In other embodiments, the semiconductor material that provides each source/drain region 510 may comprise a different semiconductor material than that which provides semiconductor channel material layer 140. For example, the semiconductor material that provides each source/drain region 510 may comprise a silicon germanium alloy, while semiconductor channel material layer 140 may comprise silicon.

The dopant that is present in each source/drain region 510 can be either a p-type dopant or an n-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium, and indium. “N-type” refers to the addition of impurities that contributes free electrons to an intrinsic semiconductor. In a silicon containing semiconductor material, examples of n-type dopants, i.e., impurities, include, but are not limited to, antimony, arsenic, and phosphorous. In one embodiment, the dopant that can be present in each source/drain region 510 can be introduced into the precursor gas that provides each source/drain region 510. In another embodiment, the dopant can be introduced into an intrinsic semiconductor layer by utilizing one of ion implantation or gas phase doping. In one example, each source/drain region 510 comprises a silicon germanium alloy that is doped with a p-type dopant such as, for example, boron. As mentioned above, each source/drain region 510 is formed by an epitaxial growth (or deposition) process, as is defined above.

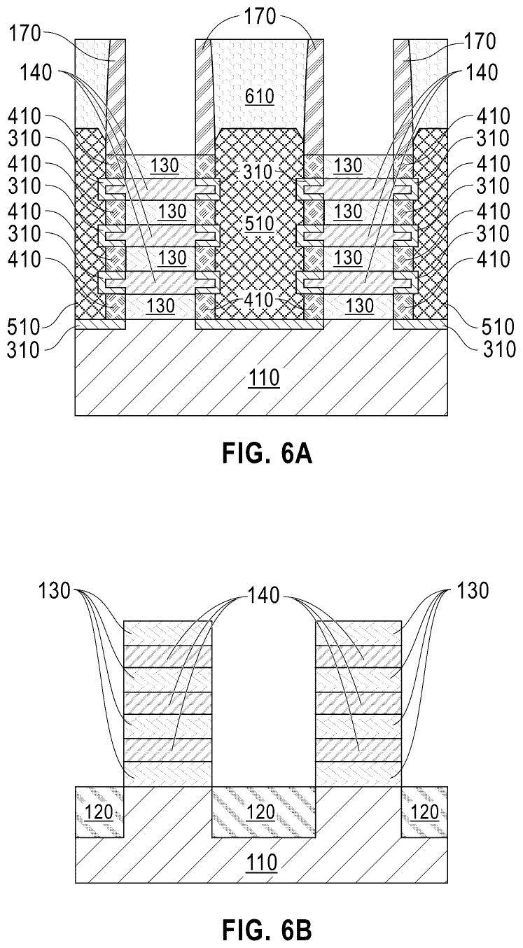

FIG. 6A depicts a first cross-sectional view, along a first direction, and FIG. 6B depicts a second cross-sectional view, along a second direction, of fabrication steps, in accordance with an embodiment of the present invention. FIGS. 6A-6B depict the formation of interlayer dielectric (ILD) 610 and the removal of each sacrificial gate structure (sacrificial gate portion 150 and sacrificial dielectric cap portion 160.

The ILD material 610 is formed above each source/drain region 510. In some embodiments, ILD material 610 covers exposed portions of sacrificial dielectric cap portion 160.

ILD material 610 may be composed of silicon dioxide, undoped silicate glass (USG), fluorosilicate glass (FSG), borophosphosilicate glass (BPSG), a spin-on low-κ dielectric layer, a chemical vapor deposition (CVD) low-k dielectric layer or any combination thereof. The term “low-κ” as used throughout the present application denotes a dielectric material that has a dielectric constant of less than silicon dioxide. In another embodiment, a self-planarizing material such as a spin-on glass (SOG) or a spin-on low-κ dielectric material such as SiLK™ can be used as ILD material 610. The use of a self-planarizing dielectric material as ILD material 610 may avoid the need to perform a subsequent planarizing step.

In one embodiment, ILD material 610 can be formed utilizing a deposition process including, for example, chemical vapor deposition (CVD), plasma enhanced chemical vapor deposition (PECVD), evaporation or spin-on coating. In some embodiments, particularly when non-self-planarizing dielectric materials are used as ILD material 610, a planarization process, such as chemical-mechanical planarization (CMP), or an etch back process follows the deposition of the dielectric material that provides ILD material 610. As is shown in FIG. 6A, ILD material 610 that is present atop each source/drain region 510 has a topmost surface that is coplanar with a topmost surface of the dielectric spacer material layer 170 that remains after any necessary planarization process.

After providing ILD material 610, sacrificial dielectric cap portion 160 is removed from atop each sacrificial gate portion 150, and thereafter each sacrificial gate portion 150 is removed to provide a gate cavity. The removal of each sacrificial dielectric cap portion 160 and each sacrificial gate portion 150 can be performed utilizing one or more anisotropic etching processes.

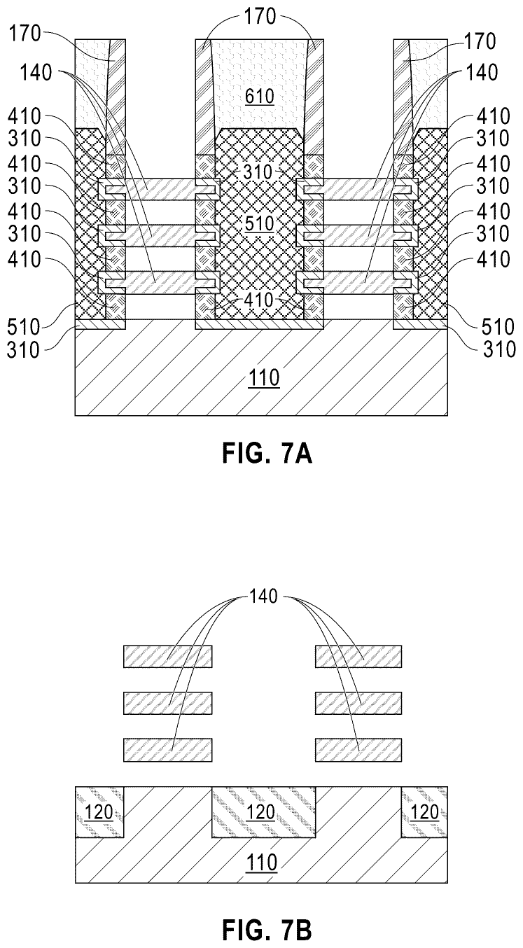

FIG. 7A depicts a first cross-sectional view, along a first direction, and FIG. 7B depicts a second cross-sectional view, along a second direction, of fabrication steps, in accordance with an embodiment of the present invention. FIGS. 7A-7B depict the removal of each recessed sacrificial semiconductor material nanosheet (i.e., sacrificial semiconductor material layer 130).

Each semiconductor channel material nanosheet (i.e., semiconductor channel material layer 140) is suspended by selectively etching each recessed sacrificial semiconductor material nanosheet (i.e., sacrificial semiconductor material layer 130) relative to each semiconductor channel material nanosheet (i.e., semiconductor channel material layer 140).

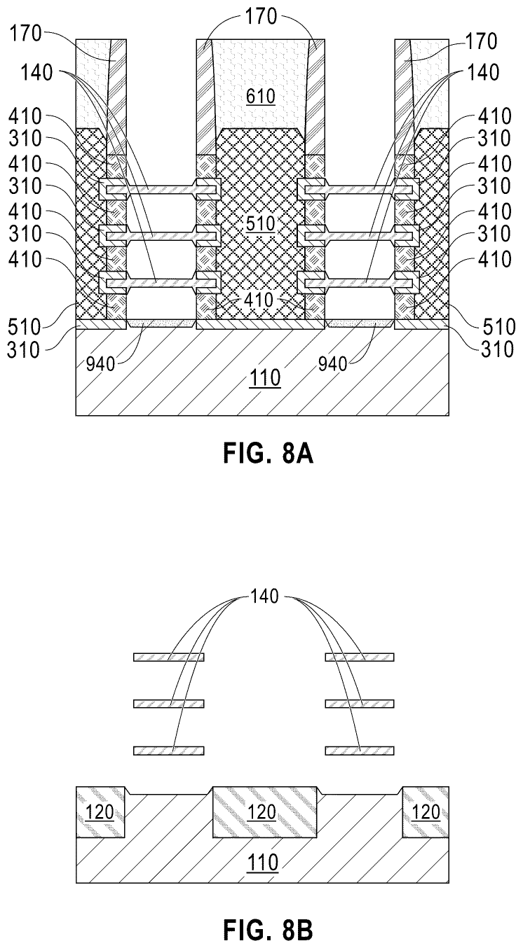

FIG. 8A depicts a first cross-sectional view, along a first direction, and FIG. 8B depicts a second cross-sectional view, along a second direction, of fabrication steps, in accordance with an embodiment of the present invention. FIGS. 8A-8B depict the trimming of exposed portions of semiconductor channel material layer 140 to a smaller size.

Exposed portions of semiconductor channel material layer 140 are trimmed. In some embodiments, a selective etching process, such as an isotropic wet or dry etch process trims the exposed portions of semiconductor channel material layer 140. In general, portions of the top and bottom surfaces of semiconductor channel material layer 140 are removed. In some embodiments, subsequent to etching semiconductor channel material layer 140, the thickness of the remaining portions of semiconductor channel material layer 140 are in the range of one to eight nm, but are not limited to this range.

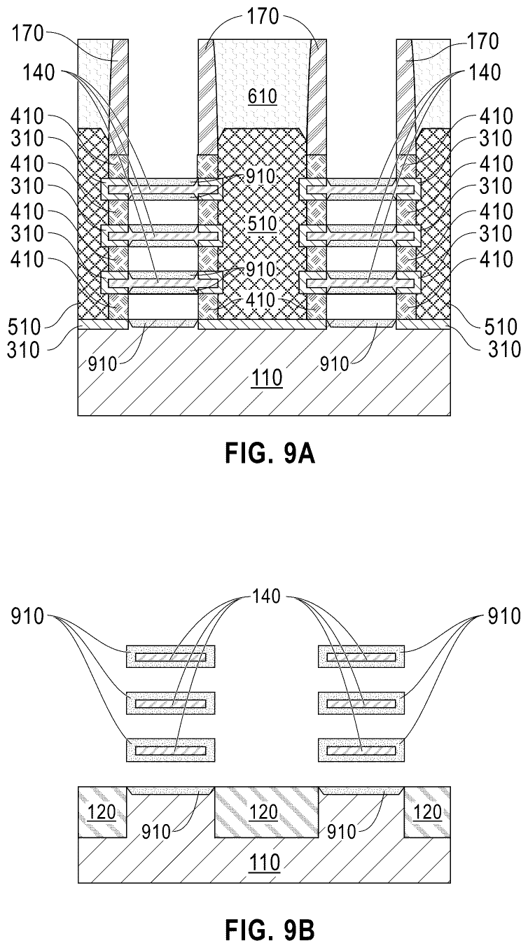

FIG. 9A depicts a first cross-sectional view, along a first direction, and FIG. 9B depicts a second cross-sectional view, along a second direction, of fabrication steps, in accordance with an embodiment of the present invention. FIGS. 9A-9B depict the growth of undoped channel material 910 on exposed surfaces of semiconductor channel material layer 140 and semiconductor substrate 110.

Undoped channel material 910 may be formed of, for example, SiGe or SiGe alloy. Undoped channel material 910 can be formed utilizing an epitaxial growth or deposition process.

The terms “epitaxially growing and/or depositing” and “epitaxially grown and/or deposited” mean the growth of a semiconductor material on a deposition surface of a semiconductor material, in which the semiconductor material being grown has the same crystalline characteristics as the semiconductor material of the deposition surface. In an epitaxial deposition process, the chemical reactants provided by the source gases are controlled and the system parameters are set so that the depositing atoms arrive at the deposition surface of the semiconductor substrate with sufficient energy to move around on the surface and orient themselves to the crystal arrangement of the atoms of the deposition surface. Therefore, an epitaxial semiconductor material has the same crystalline characteristics as the deposition surface on which it is formed.

Examples of various epitaxial growth process apparatuses that can be employed in the present application include, e.g., rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE). The temperature for epitaxial deposition typically ranges from 550° C. to 900° C. Although higher temperature typically results in faster deposition, the faster deposition may result in crystal defects and film cracking. The epitaxial growth of undoped channel material 910 on exposed surfaces of semiconductor channel material layer 140 and semiconductor substrate 110 can be performed utilizing any well-known precursor gas or gas mixture. Carrier gases like hydrogen, nitrogen, helium and argon can be used.

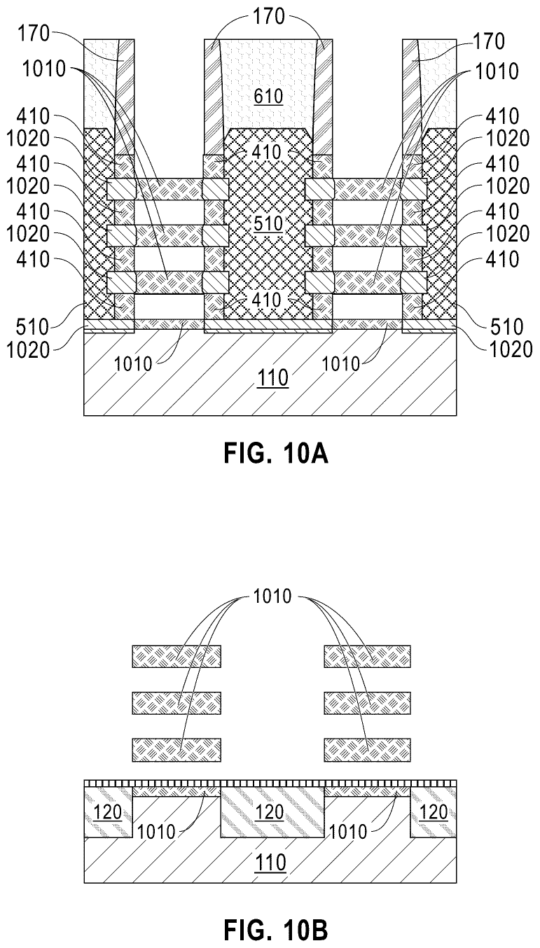

FIG. 10A depicts a first cross-sectional view, along a first direction, and FIG. 10B depicts a second cross-sectional view, along a second direction, of fabrication steps, in accordance with an embodiment of the present invention. FIGS. 10A-10B depict the structure subsequent to a thermal mix process resulting in the formation of each continuous common material channel nanosheet (semiconductor channel portion 1010, SDE portion 1020).

A thermal mix process is a high-temperature thermal anneal which is performed in an inert environment, such as a noble gas or nitrogen. The high temperature thermal anneal results in the migration of germanium atoms from undoped channel material 910 and thin-doped layer 310 into semiconductor channel material layer 140, thus forming each continuous common material channel nanosheet (semiconductor channel portion 1010, SDE portion 1020). Due to the lack of an oxidizing environment in a thermal mix process, no silicon oxide is formed on the exposed portions of each continuous common material channel nanosheet (semiconductor channel portion 1010, SDE portion 1020). As a result of the thermal mix process, a similar migration of germanium atoms from the bottom portion of thin-doped layer 310 into semiconductor substrate 110, and, in some embodiments, this may also be considered a SDE portion 1020. In some embodiments, subsequent to the thermal mix process, each continuous common material channel nanosheet (semiconductor channel portion 1010, SDE portion 1020) has a uniform germanium (Ge) profile. In some embodiments, subsequent to the thermal mix process, each continuous common material channel nanosheet (semiconductor channel portion 1010, SDE portion 1020) has a graded germanium (Ge) profile.

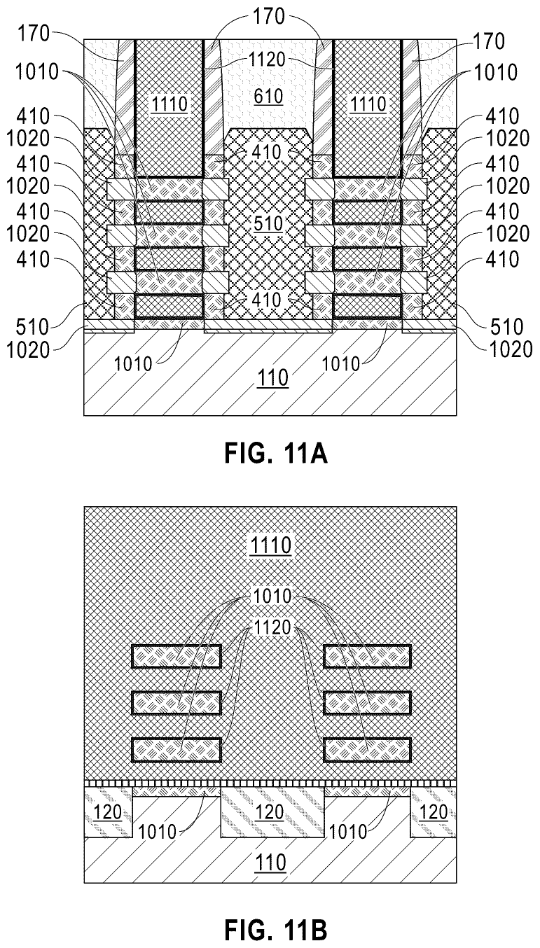

FIG. 11A depicts a first cross-sectional view, along a first direction, and FIG. 11B depicts a second cross-sectional view, along a second direction, of fabrication steps, in accordance with an embodiment of the present invention. FIGS. 11A-11B depict the formation of a functional gate structure (gate conductor portion 1110, gate dielectric portion 1120 around a physically exposed surface of each semiconductor channel portion 1010 of each continuous common material channel nanosheet (semiconductor channel portion 1010, SDE portion 1020).

A functional gate structure (gate conductor portion 1110, gate dielectric portion 1120) is then formed in each gate cavity and surrounding a physically exposed surface of each semiconductor channel portion 1010 of each continuous common material channel nanosheet (semiconductor channel portion 1010, SDE portion 1020). By “functional gate structure” it is meant a permanent gate structure used to control output current (i.e., flow of carriers in the channel) of a semiconducting device through electrical or magnetic fields. Although a single functional gate structure is described and illustrated, a plurality of functional gate structures can be formed.

The functional gate structure (gate conductor portion 1110, gate dielectric portion 1120) may include gate dielectric portion 1120 and gate conductor portion 1110. Gate dielectric portion 1120 may include a gate dielectric material. The gate dielectric material that provides gate dielectric portion 1120 can be an oxide, nitride, and/or oxynitride. In one example, the gate dielectric material that provides gate dielectric portion 1120 can be a high-κ material having a dielectric constant greater than silicon dioxide. Exemplary high-κ dielectrics include, but are not limited to, HfO₂, ZrO₂, La₂O₃, Al₂O₃, TiO₂, SrTiO₃, LaAlO₃, Y₂O₃, HfOₓN_{y}, ZrOₓN_{y}, La₂OₓN_{y}, Al₂OₓN_{y}, TiOₓN_{y}, SrTiOₓN_{y}, LaAlOₓN_{y}, Y₂OₓN_{y}, SiON, SiNₓ, a silicate thereof, and an alloy thereof. Each value of x is independently from 0.5 to 3 and each value of y is independently from 0 to 2. In some embodiments, a multilayered gate dielectric structure comprising different gate dielectric materials, e.g., silicon dioxide, and a high-κ gate dielectric, can be formed and used as gate dielectric portion 1120.

The gate dielectric material used in providing gate dielectric portion 1120 can be formed by any deposition process including, for example, chemical vapor deposition (CVD), plasma enhanced chemical vapor deposition (PECVD), physical vapor deposition (PVD), sputtering, or atomic layer deposition. In one embodiment of the present application, the gate dielectric material used in providing gate dielectric portion 1120 can have a thickness in a range from 1 nm to 10 nm. Other thicknesses that are lesser than, or greater than, the aforementioned thickness range can also be employed for the gate dielectric material that may provide gate dielectric portion 1120.

Gate conductor portion 1110 can include a gate conductor material. The gate conductor material used in providing gate conductor portion 1110 can include any conductive material including, for example, doped polysilicon, an elemental metal (e.g., tungsten, titanium, tantalum, aluminum, nickel, ruthenium, palladium and platinum), an alloy of at least two elemental metals, an elemental metal nitride (e.g., tungsten nitride, aluminum nitride, and titanium nitride), an elemental metal silicide (e.g., tungsten silicide, nickel silicide, and titanium silicide), or multilayered combinations thereof. In one embodiment, gate conductor portion 1110 may comprise an nFET gate metal. In another embodiment, gate conductor portion 1110 may comprise a pFET gate metal. When multiple gate cavities are formed, it is possible to form a nFET in a first set of the gate cavities and wrapping around some of the semiconductor channel material nanosheets (i.e., semiconductor channel portion 1010 of each continuous common material channel nanosheet (semiconductor channel portion 1010, SDE portion 1020)) and a pFET in a second set of the gate cavities and wrapping around some of the semiconductor channel material nanosheets (i.e., semiconductor channel portion 1010 of each continuous common material channel nanosheet (semiconductor channel portion 1010, SDE portion 1020)).

The gate conductor material used in providing gate conductor portion 1110 can be formed utilizing a deposition process including, for example, chemical vapor deposition (CVD), plasma enhanced chemical vapor deposition (PECVD), physical vapor deposition (PVD), sputtering, atomic layer deposition (ALD) or other like deposition processes. When a metal silicide is formed, a conventional silicidation process is employed. In one embodiment, the gate conductor material used in providing gate conductor portion 1110 can have a thickness from 50 nm to 200 nm. Other thicknesses that are lesser than, or greater than, the aforementioned thickness range can also be employed for the gate conductor material used in providing gate conductor portion 1110.

The functional gate structure (gate conductor portion 1110, gate dielectric portion 1120) can be formed by providing a functional gate material stack of the gate dielectric material, and the gate conductor material. A planarization process may follow the formation of the functional gate material stack.

In embodiments, the resulting semiconductor structure is a gate-all-around nanosheet transistor with a continuous and common material channel (continuous common material channel nanosheet (semiconductor channel portion 1010, SDE portion 1020)) spanning from a source (source/drain region 510) to a drain (source/drain region 510). SDE regions (SDE portion 1020) under the inner spacers (inner spacers 410) are formed with doped SiGe and the SDE dopants may be a different dopant species than the source/drain (source/drain region 510) dopants. The continuous and common material channel (continuous common material channel nanosheet (semiconductor channel portion 1010, SDE portion 1020)) is formed with undoped SiGe. The Ge profile of the continuous and common material channel (continuous common material channel nanosheet (semiconductor channel portion 1010, SDE portion 1020)) is uniform or graded.

The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the invention. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A semiconductor structure comprising:
one or more stacked and suspended silicon germanium (SiGe) semiconductor channel material nanosheets located above a semiconductor substrate;
a functional gate structure surrounding a portion of each SiGe semiconductor channel material nanosheet of the one or more stacked and suspended SiGe semiconductor channel material nanosheets; and
a source/drain region on each side of the functional gate structure and physically contacting sidewalls of each SiGe semiconductor channel material nanosheet of the one or more stacked and suspended SiGe semiconductor channel material nanosheets.

2. The semiconductor structure of claim 1, wherein each SiGe semiconductor channel material nanosheet comprises a portion formed with doped SiGe, the portion located between inner gate spacers.

3. The semiconductor structure of claim 1, wherein each SiGe semiconductor channel material nanosheet has a uniform germanium (Ge) profile.

4. The semiconductor structure of claim 1, wherein each SiGe semiconductor channel material nanosheet has a graded germanium (Ge) profile.

5. The semiconductor structure of claim 1, further comprising an interlayer dielectric (ILD) material located above each source/drain region and laterally adjacent to each contact region.

6. The semiconductor structure of claim 1, further comprising inner gate spacers contacting sidewalls of the functional gate structure and located on an outer portion of each SiGe semiconductor channel material nanosheet of the one or more stacked and suspended SiGe semiconductor channel material nanosheets.

7. The semiconductor structure of claim 1, wherein the sidewalls of each SiGe semiconductor channel material nanosheet of the one or more stacked and suspended SiGe semiconductor channel material nanosheets are vertically aligned to one another.

8. The semiconductor structure of claim 1, wherein each functional gate structure comprises (i) a gate dielectric portion physically contacting the SiGe semiconductor channel material nanosheet and (ii) a gate conductor portion physically contacting the gate dielectric portion.

9. The semiconductor structure of claim 1, further comprising a layer of SiGe material on top of the semiconductor substrate and beneath each source/drain region and an inner gate spacer.

10. The semiconductor structure of claim 1, further comprising, a layer of SiGe material on top of the semiconductor substrate and beneath the functional gate structure.

11. The semiconductor structure of claim 9, further comprising a region that includes a shallow trench isolation (STI) material that is physically contacting the semiconductor substrate, the functional gate structure, and the layer of SiGe material.

12. The semiconductor structure of claim 1, wherein the semiconductor substrate is composed of a different semiconductor material than each SiGe semiconductor channel material nanosheets.

13. A semiconductor structure comprising:
one or more stacked and suspended silicon germanium (SiGe) nanosheets located above a semiconductor substrate, wherein each SiGe nanosheet comprises a plurality of portions comprising:
a first portion between two inner gate spacers, the first portion formed with doped SiGe; and
a second portion formed with undoped SiGe;
a functional gate structure surrounding the second portion of each SiGe semiconductor channel material nanosheet of the one or more stacked and suspended SiGe semiconductor channel material nanosheets; and
a source/drain region on each side of the functional gate structure and physically contacting sidewalls of each SiGe semiconductor channel material nanosheet of the one or more stacked and suspended SiGe semiconductor channel material nanosheets.

14. A method of forming a semiconductor structure, the method comprising:
providing a nanosheet stack of alternating nanosheets of a sacrificial semiconductor material nanosheet and a semiconductor channel material nanosheet located on a surface of a semiconductor substrate, wherein a sacrificial gate structure and a dielectric spacer material layer straddle over the nanosheet stack;
recessing end portions of each of the sacrificial semiconductor material nanosheets to provide a gap between each of the semiconductor channel material nanosheets;
forming a thin-doped silicon germanium (SiGe) layer on exposed surfaces of the semiconductor channel material nanosheet and the semiconductor substrate;
forming an additional dielectric spacer material layer within each gap;
forming a source/drain region by epitaxial growth of a semiconductor material on physically exposed sidewalls of the thin-doped SiGe layer;
removing the sacrificial gate structure;
removing each sacrificial semiconductor material nanosheet to suspend each semiconductor channel material nanosheet;
trimming exposed portions of each semiconductor channel material nanosheet;
forming undoped SiGe on exposed portions of each semiconductor channel;
performing a thermal mix, resulting in the undoped SiGe, the thin-doped SiGe, and each semiconductor channel becoming one or more SiGe semiconductor channel material nanosheets; and
forming a functional gate structure in regions occupied by the sacrificial gate structure and each sacrificial semiconductor material nanosheet, wherein the functional gate structure wraps around each suspended SiGe semiconductor channel material nanosheet.

15. The method of claim 14, wherein recessing the end portions of each of the sacrificial semiconductor material nanosheets causes a thinning of each of the semiconductor material nanosheets.

16. The method of claim 14, wherein forming undoped SiGe on exposed portions of each semiconductor channel further comprises forming additional undoped SiGe on exposed portions of the semiconductor substrate.

17. The method of claim 14, wherein recessing the end portions of each sacrificial semiconductor material nanosheet comprises a lateral etching process.

18. The method of claim 14, wherein:
each sacrificial semiconductor material nanosheet is composed of SiGe; and
each semiconductor channel material nanosheet is composed of silicon (Si).

19. The method of claim 14, wherein the nanosheet stack of alternating nanosheets comprises one or more layers of the semiconductor channel material nanosheets.

20. The method of claim 14, where sidewalls of each SiGe semiconductor channel material nanosheet of a one or more stacked SiGe semiconductor channel material nanosheets are vertically aligned to one another.
